(19) United States
(12) Patent Application Publication
(10) Pub. No.: US 2025/0366278 A1
(43) Pub. Date: Nov. 27, 2025

(54) LIGHT-EMITTING DIODE BACKPLANE FOR LIGHTING AND DISPLAY

(71) Applicant: GM Global Technology Operations LLC, Detroit, MI (US)

(72) Inventor: Jonglee Park, Novi, MI (US)

(73) Assignee: GM Global Technology Operations LLC, Detroit, MI (US)

(21) Appl. No.: 18/669,726

(22) Filed: May 21, 2024

(51) Int. Cl. H01L 33/62; B60Q 1/50; H01L 25/16

(52) U.S. Cl. CPC H10H 20/857; H01L 25/167; B60Q 1/5035

(57) ABSTRACT

A display backplane comprising a substrate comprising traces for generating display information based on electrical signals from one or more controllers and one or more drivers and one or more light-emitting diode(s) (LEDs) arranged on the substrate. The display backplane further comprising a non-matrix driving circuit layer communicatively coupled to at least one of the one or more LEDs in a lighting region and configured to provide high efficiency lighting, a matrix driving circuit layer communicatively coupled to at least one of the one or more LEDs in a display region and configured to generate images and videos, and an insulator layer arranged between the non-matrix driving circuit layer and the matrix driving circuit layer and configured to prevent electrical interference between the circuit layers.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to lighting and display systems and, more particularly, to configurations that integrate lighting and display systems on one backplane.

In general, vehicles can be equipped with various interior and exterior lighting and/or display systems. These systems commonly include a backplane which can have a substrate with a matrix driving circuit or a non-matrix driving circuit for controlling and/or operating one or more light-emitting diode(s) (LEDs). Existing systems do not provide a backplane that is configured for both high efficiency lighting and displaying videos and/or photos. One or more aspects of the present disclosure addresses one or more shortcomings of these systems.

### SUMMARY

In one configuration, a lighting and display backplane is provided and includes a substrate including traces for generating display information based on electrical signals from one or more controllers and one or more drivers and one or more light-emitting diode(s) (LEDs) arranged on the substrate. The display backplane further includes a non-matrix driving circuit layer communicatively coupled to at least one of the one or more LEDs in a lighting region and configured to provide high efficiency lighting, a matrix driving circuit layer communicatively coupled to at least one of the one or more LEDs in a display region and configured to generate images and videos, and an insulator layer arranged between the non-matrix driving circuit layer and the matrix driving circuit layer and configured to prevent electrical interference between the circuit layers.

The lighting and display backplane may include one or more of the following optional features. For example, the one or more LEDs can each include a red LED, a green LED, and a blue LED. Additionally, at least one hole can be arranged in the matrix driving circuit layer and the insulator layer. The one or more LEDs can be coupled to the non-matrix driving circuit layer through the at least one hole or one of the red LED, the green LED, or the blue LED of the one or more LEDs can be coupled to the non-matrix driving circuit layer through the at least one hole.

According to at least one aspect, the one or more LEDs can include one or more multi-purpose LEDs and one or more display LEDs. The one or more multi-purpose LEDs can be arranged in the lighting region and the one or more display LEDs can be arranged in the display region. The multi-purpose LEDs can coupled to the non-matrix driving circuit layer and the matrix driving circuit layer, and the display LEDs can be coupled to the matrix driving circuit layer.

According to another aspect, the non-matrix driving circuit layer can be configured to drive the one or more LEDs for a first time interval and the matrix driving circuit layer can be configured drive the one or more LEDs for a second time interval. The first time interval can be greater than the second time interval.

In another configuration, a vehicle is provided and includes a vehicle body and a lighting and display system coupled to the vehicle body. The lighting and display system includes one or more controllers, one or more drivers, and a backplane communicatively coupled to the one or more controllers and the one or more drivers. The backplane including a substrate including traces for generating display information and coupled to the one or more controllers and the one or more drivers and one or more light-emitting diode(s) (LEDs) arranged on the substrate. The backplane further including a non-matrix driving circuit layer coupled to at least one of the one or more LEDs in a lighting region and configured to provide high efficiency lighting, a matrix driving circuit layer coupled to at least one of the one or more LEDs in a display region and configured to generate images and videos, and an insulator layer arranged between the non-matrix driving circuit layer and the matrix driving circuit layer and configured to prevent electrical interference between the circuit layers.

The vehicle may include one or more of the following optional features. For example, the one or more LEDs can each include a red LED, a green LED, and a blue LED. Additionally, at least one hole can be arranged in the matrix driving circuit layer and the insulator layer. The one or more LEDs can be coupled to the non-matrix driving circuit layer through the at least one hole or one of the red LED, the green LED, or the blue LED of the one or more LEDs can be coupled to the non-matrix driving circuit layer through the at least one hole.

According to at least one aspect, the one or more LEDs can include one or more multi-purpose LEDs and one or more display LEDs. The one or more multi-purpose LEDs can be arranged in the lighting region and the one or more display LEDs can be arranged in the display region. The multi-purpose LEDs can coupled to the non-matrix driving circuit layer and the matrix driving circuit layer, and the display LEDs can be coupled to the matrix driving circuit layer.

According to another aspect, the non-matrix driving circuit layer can be configured to drive the one or more LEDs for a first time interval and the matrix driving circuit layer can be configured drive the one or more LEDs for a second time interval. The first time interval can be greater than the second time interval.

### BRIEF DESCRIPTION OF THE DRAWINGS

The drawings described herein are for illustrative purposes only of selected configurations and are not intended to limit the scope of the present disclosure.

FIG. 1 is a schematic rear view of a vehicle according to principles of the present disclosure;

FIG. 2 is a schematic view of the vehicle of FIG. 1 including a lighting and display system, a vehicle management system, and a battery;

FIG. 3 is a partial end view of a backplane of the lighting and display system of FIG. 2;

FIG. 4 is a top view a first or non-matrix driving circuit layer of the backplane of FIG. 3;

FIG. 5 is a top view of a second or matrix driving circuit layer of the backplane of FIG. 3;

FIG. 6 is a partial end view of another configuration of a backplane; and

FIG. 7 is a schematic view of another configuration of a lighting and display system.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICS (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Display systems typically include a backplane with a matrix driving circuit that is coupled to and communicates with one or more LEDs to display videos and/or images. On the other hand, lighting systems commonly include a backplane with a non-matrix driving circuit that is coupled to and communicates with one or more LEDs. Lighting systems are typically configured so that the LEDs can be held in an “on” state for a longer duration when compared to display systems. In at least some instances, a single backplane that is configured to display videos and/or images and provide high efficiency lighting capabilities can be desirable, especially if space is limited.

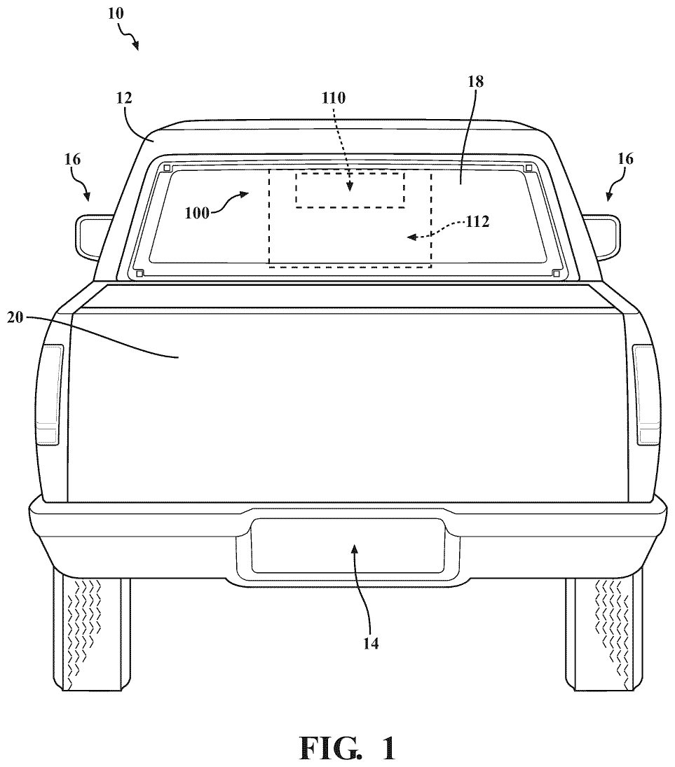

With reference to FIG. 1, a vehicle 10 is provided and includes a vehicle body 12. The vehicle body 12 has a rear end 14 and a front end that extends into the page and is opposite the rear end 14. The vehicle 10 can have one or more closures, such as one or more doors 16, one or more windows (e.g., a windshield, a rear window, one or more passenger door windows, etc.) 18, and a tailgate 20, for example. The vehicle 10 also includes a lighting and display system 100 and, in the present illustrative configuration, is arranged on the rear window 18. Note, the lighting and display system 100 can be configured for non-vehicle examples as well.

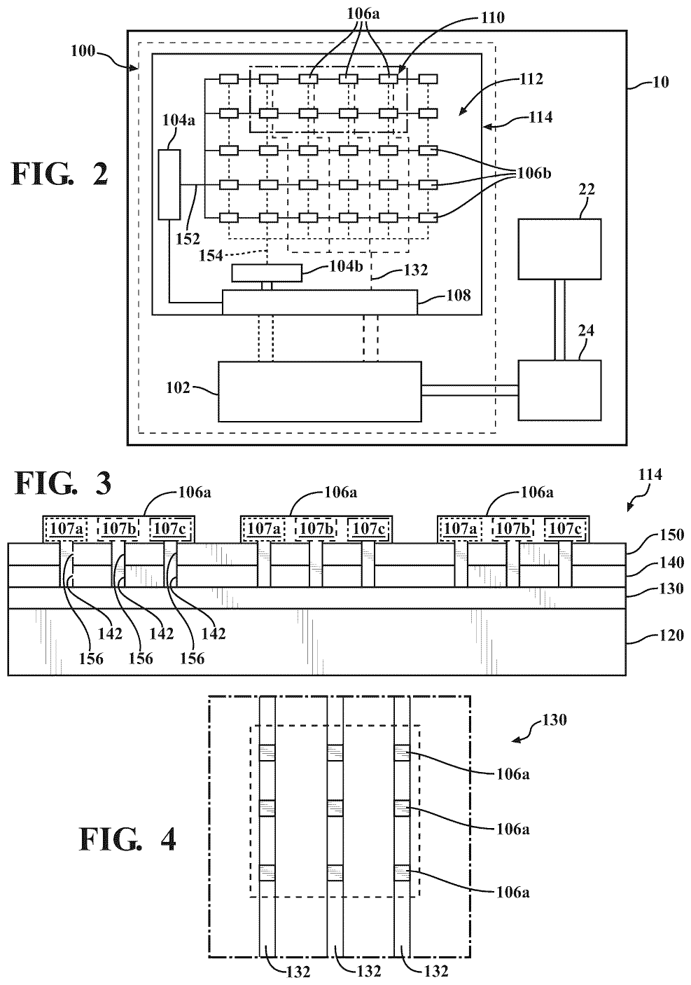

With reference to FIG. 2, the vehicle 10 can further include one or more batteries 22 that are communicatively coupled to the lighting and display system 100 and are configured for powering electronics of the vehicle 10. Note, in another configuration, the lighting and display system 100 can be configured to receive power from a 120 volt AC power supply. The vehicle 10 can include a vehicle management system 24 that is communicatively coupled to the lighting and display system 100 and can be configured to control and manage operations of the vehicle 10. According to one aspect, the vehicle management system 24 can provide an input or instructions to one or more controllers 102 (hereinafter, the controller 102) of the lighting and display system 100.

Additionally or alternatively, the lighting and display system 100 can include one or more drivers 104 communicatively coupled to one or more light-emitting diode(s) (LEDs) 106. For instance, the one or more drivers 104 can include a first or scan driver 104a and a second or data driver 104b (hereinafter, also referred to as the drivers 104). The drivers 104 can also be communicatively coupled to the controller 102 via one or more connectors 108. The controller 102 and/or the drivers 104 can be configured to provide power and/or electrical signals to operate the one or more LEDs 106. With reference again to FIG. 2, the LEDs 106 can include multi-purpose LEDs 106a that can be configured for high efficiency lighting and displaying videos and/or images. Additionally, the LEDs 106 can include display LEDs 106b that are configured for displaying videos and/or images. The multi-purpose LEDs 106a can be arranged in a first or lighting region 110 of the lighting and display system 100 that is configured for high efficiency lighting and displaying videos and/or images. The display LEDs 106b can be arranged in a second or display region 112 of the lighting and display system 100 that is configured for displaying videos and/or images. According to one aspect, the multi-purpose LEDs 106a and the display LEDs 106b are arranged with respect to one another (i.e., arranged in rows and columns), as shown in FIG. 2. According to another aspect, as shown in FIG. 3, the multi-purpose LEDs 106a and the display LEDs 106b can each have a first or red LED 107a, a second or green LED 107b, and a third or blue LED 107c.

With continued reference to FIG. 3, the lighting and display system 100 can include a backplane 114 that includes a substrate 120, a first or non-matrix driving circuit layer 130, an insulator layer 140, and a second or matrix driving circuit layer 150. The backplane 114 can be arranged to include the lighting region 110 and the display region 112 and, according to at least one aspect, the display region 112 can at least partially overlap the lighting region 110 on the backplane 114. In other words, at least a portion of the lighting region 110 can be operated in conjunction with the display region 112.

The substrate 120 can provide support for the controller 102, the drivers 104, and the one or more layers of the backplane 114. The substrate 120 can be made of glass, polymer, or another material that is not electrically conductive. The substrate 120 can have one or more traces coupled to or embedded within the substrate 120 so that electrical signals can be communicated across the substrate 120.

The non-matrix driving circuit layer 130 can be arranged on or coupled to the substrate 120, as shown in FIG. 3. With reference to FIGS. 2 and 4, the non-matrix driving circuit layer 130 can include one or more lighting traces 132 that are coupled to or embedded within the non-matrix driving circuit layer 130. The lighting traces 132 can be coupled to the multi-purpose LEDs 106a and to the controller 102 via the connector 108. The multi-purpose LEDs 106a can be held in an “on” state for a first time interval or duration that allows for a hazard sign, a braking sign, a message, etc. to be presented in the lighting region 110 of the lighting and display system 100. In other words, the non-matrix driving circuit layer 130 can be configured for high efficiency lighting.

The insulator layer 140 can be arranged on or coupled to the non-matrix driving layer 130, as shown in FIG. 3. The insulator layer 140 can be made of a non-conductive material such as epoxy, silicon, or another material that can prevent electrical interference between the non-matrix driving circuit layer 130 and the matrix driving circuit layer 150. The insulator layer 140 can include one or more holes 142 so that the multi-purpose LEDs 106a can be coupled to the non-matrix driving circuit layer 130. In at least one example, the insulator layer 140 can include a hole 142 for each of the red LED 107a, the green LED 107b, and the blue LED 107c of each of the multi-purpose LEDs 106a. The insulator 140 can also be configured so that the multi-purpose LEDs 106a can be coupled to the non-matrix driving circuit layer 130 to provide monochrome lighting arrangements. For instance, with reference to FIG. 6, the insulator layer 140′ of the backplane 114′ includes a single hole 142 for one of the red LED 107a, the green LED 107b, or the blue LED 107c for each of the multi-purpose LEDs 106a.

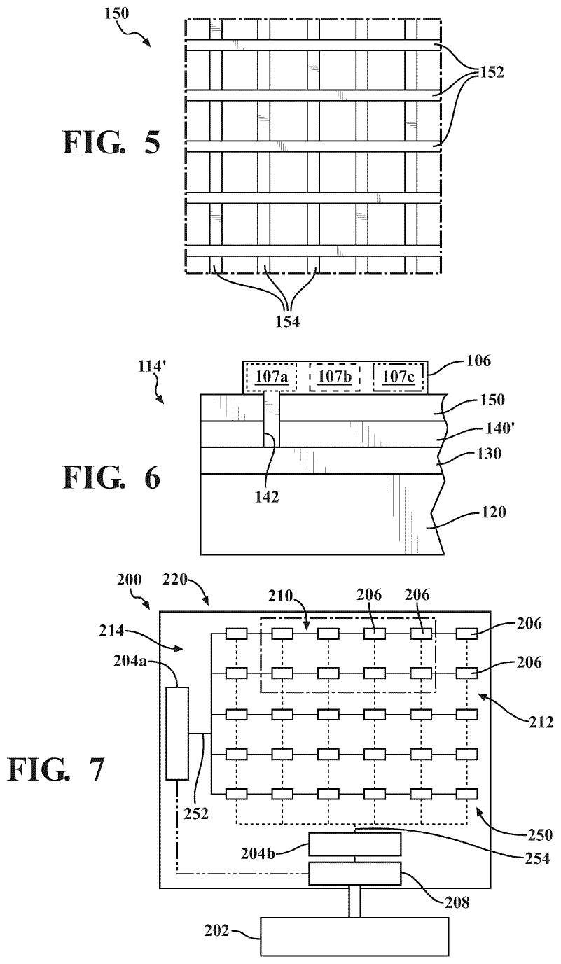

The matrix driving circuit layer 150 can be arranged on or coupled to the insulator layer 140, as shown in FIG. 3. With reference to FIGS. 2 and 5, the matrix driving circuit layer 150 can include one or more first or scan bus lines 152 that are coupled to the scan driver 104a and to one or more of the multi-purpose LEDs 106a and one or more of the display LEDs 106b. Additionally, the matrix driving circuit layer 150 can include one or more second or data bus lines 154 that are coupled to the data driver 104b and to one or more of the multi-purpose LEDs 106a and one or more of the display LEDs 106b. The matrix driving circuit layer 150 can include one or more holes 156 that are concentric with the one or more holes 142 of the insulator layer 140 so that the multi-purpose LEDs 106a can be communicatively coupled to the non-matrix driving circuit layer 130. According to one aspect, in operation, the multi-purpose LEDs 106a and the display LEDs 106b can be controlled via the scan driver 104a and the data driver 104b to provide (i.e., display) videos and/or photos.

According to another aspect, the non-matrix driving circuit layer 130 and the matrix driving layer can power one or more of the LEDs 106 simultaneously. In other words, the non-matrix driving circuit layer 130 can communicate electrical signals to the one or more multi-purpose LEDs 106a to generate a high efficiency lighting arrangement in the lighting region 110, and the matrix driving circuit layer 150 can communicate electrical signals to the one or more display LEDs 106b to display a video or a photo in the display region 112. Thus, the display region 112 can be used to enhance the high efficiency lighting arrangement in the lighting region 110.

FIG. 7 illustrates another illustrative configuration of a lighting and display system 200. This configuration is similar in many respects to the configurations in FIGS. 1-6. Accordingly, the descriptions of the configurations are hereby incorporated into one another, and description of subject matter common to the configurations generally may not be repeated.

The lighting and display system 200 can provide lighting arrangements and display videos and/or photos on a backplane 214 via a matrix driving layer 250. The lighting and display system 200 can include a first or lighting region 210 and a second or display region 212.

A controller 202 can be coupled to a first or scan driver 204a and a second or data driver 204b via a connector 208. The scan driver 204a can communicate with one or more LEDs 206 via first or scan bus lines 252. The data driver 204b can communicate with the one or more LEDs 206 via second or data bus lines 254.

In the present configuration, the lighting region 210 can include or more of the LEDs 206 configured in a rectangular or square arrangement. An electrical signal (i.e., a driving voltage) of the matrix driving layer 250 can be applied to the LEDs 206 arranged in the lighting region 210 through the scan bus lines 252 and the data bus lines 254. As such, the lighting and display system 200 can provide high efficiency lighting for at least a portion of the backplane 214.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A lighting and display backplane comprising:
a substrate comprising traces for generating display information based on electrical signals from one or more controllers and one or more drivers;
one or more light-emitting diode(s) (LEDs) arranged on the substrate;
a non-matrix driving circuit layer communicatively coupled to at least one of the one or more LEDs in a lighting region and configured to provide high efficiency lighting;
a matrix driving circuit layer communicatively coupled to at least one of the one or more LEDs in a display region and configured to generate images and videos; and
an insulator layer arranged between the non-matrix driving circuit layer and the matrix driving circuit layer and configured to prevent electrical interference between the circuit layers.

2. The lighting and display backplane of claim 1, wherein the one or more LEDs each comprise a red LED, a green LED, and a blue LED.

3. The lighting and display backplane of claim 2, wherein at least one hole is arranged in the matrix driving circuit layer and the insulator layer.

4. The lighting and display backplane of claim 3, wherein the one or more LEDs is coupled to the non-matrix driving circuit layer through the at least one hole.

5. The lighting and display backplane of claim 3, wherein one of the red LED, the green LED, or the blue LED of the one or more LEDs is coupled to the non-matrix driving circuit layer through the at least one hole.

6. The lighting and display backplane of claim 1, wherein the one or more LEDs comprises one or more multi-purpose LEDs and one or more display LEDs.

7. The lighting and display backplane of claim 6, wherein the one or more multi-purpose LEDs are arranged in the lighting region and the one or more display LEDs are arranged in the display region.

8. The lighting and display backplane of claim 7, wherein the multi-purpose LEDs are coupled to the non-matrix driving circuit layer and the matrix driving circuit layer, and the display LEDs are coupled to the matrix driving circuit layer.

9. The lighting and display backplane of claim 1, wherein the non-matrix driving circuit layer is configured to drive the one or more LEDs for a first time interval and the matrix driving circuit layer is configured drive the one or more LEDs for a second time interval.

10. The lighting and display backplane of claim 9, wherein the first time interval is greater than the second time interval.

11. A vehicle, comprising:
a vehicle body; and
a lighting and display system coupled to the vehicle body, comprising:
one or more controllers;
one or more drivers; and
a backplane communicatively coupled to the one or more controllers and the one or more drivers, comprising:
a substrate comprising traces for generating display information and coupled to the one or more controllers and the one or more drivers,
one or more light-emitting diode(s) (LEDs) arranged on the substrate,
a non-matrix driving circuit layer coupled to at least one of the one or more LEDs in a lighting region and configured to provide high efficiency lighting,
a matrix driving circuit layer coupled to at least one of the one or more LEDs in a display region and configured to generate images and videos, and
an insulator layer arranged between the non-matrix driving circuit layer and the matrix driving circuit layer and configured to prevent electrical interference between the circuit layers.

12. The vehicle of claim 11, wherein the one or more LEDs each comprises a red LED, a green LED, and a blue LED.

13. The vehicle of claim 12, wherein at least one hole is arranged in the matrix driving circuit layer and the insulator layer.

14. The vehicle of claim 13, wherein the one or more LEDs are coupled to the non-matrix driving circuit layer through the at least one hole.

15. The vehicle of claim 13, wherein one of the red LED, the green LED, or the blue LED of the one or more LEDs is coupled to the non-matrix driving circuit layer through the at least one hole.

16. The vehicle of claim 11, wherein the one or more LEDs comprises one or more multi-purpose LEDs and one or more display LEDs.

17. The vehicle of claim 16, wherein the one or more multi-purpose LEDs are arranged in the lighting region and the one or more display LEDs are arranged in the display region.

18. The vehicle of claim 17, wherein the multi-purpose LEDs are coupled to the non-matrix driving circuit layer and the matrix driving circuit layer, and the display LEDs are coupled to the matrix driving circuit layer.

19. The vehicle of claim 11, wherein the non-matrix driving circuit layer is configured to drive the one or more LEDs for a first time interval and the matrix driving circuit layer is configured drive the one or more LEDs for a second time interval.

20. The vehicle of claim 19, wherein the first time interval is greater than the second time interval.
